(19) United States
(12) Patent Application Publication
(10) Pub. No.: US 2026/0305184 A1
(43) Pub. Date: Oct. 1, 2026

(54) METHOD OF FORMING CHALCOGENIDE-BASED THIN FILM USING ATOMIC LAYER DEPOSITION PROCESS AND METHOD OF MANUFACTURING NON-VOLATILE MEMORY DEVICE USING THE SAME

(71) Applicants: SK hynix Inc., Icheon-si Gyeonggi-do (KR); FOUNDATION FOR RESEARCH AND BUSINESS, SEOUL NATIONAL UNIVERSITY OF SCIENCE AND TECHNOLOGY, Seoul (KR)

(72) Inventors: JUNYOUNG LIM, Icheon-si Gyeonggi-do (KR); JUNKU AHN, Icheon-si Gyeonggi-do (KR); BYUNGJOON CHOI, Seoul (KR); Ye Bin WEON, Seoul (KR); Hyun Wook KIM, Seoul (KR)

(73) Assignees: SK hynix Inc., Icheon-si Gyeonggi-do (KR); FOUNDATION FOR RESEARCH AND BUSINESS, SEOUL NATIONAL UNIVERSITY OF SCIENCE AND TECHNOLOGY, Seoul (KR)

(21) Appl. No.: 19/337,548

(22) Filed: Sep. 23, 2025

(30) Foreign Application Priority Data
Mar. 26, 2025 (KR) 10-2025-0038619

(51) Int. Cl. H10N 70/00; H10B 63/10

(52) U.S. Cl. CPC H10N 70/023; H10B 63/10; H10N 70/8825

(57) ABSTRACT

A method for forming a chalcogenide-based thin film using an atomic layer deposition process, and a method for manufacturing a non-volatile memory device using the same, includes supplying a first source gas including a Ge precursor having a +2 oxidation state of Ge into a reaction chamber equipped with a substrate, supplying a first purge gas into the reaction chamber, supplying into the reaction chamber a second source gas including a Se precursor and a first co-reactant gas to promote a reaction between the Ge precursor and the Se precursor, and supplying a second purge gas into the reaction chamber. The method also includes supplying a third source gas including an In precursor into the reaction chamber, supplying a third purge gas into the reaction chamber, supplying a second co-reactant gas into the reaction chamber to promote a reaction of the third source gas including the In precursor and the second source gas, and supplying a fourth purge gas into the reaction chamber. A supercycle is repeated, the supercycle including repeating the first step through the fourth step 7 to 13 times and performing the fifth step through the eighth step once thereafter.

### CROSS-REFERENCE TO RELATED APPLICATION

The present application claims priority under 35 U.S.C. § 119(a) to Korean Patent Application No. 10-2025-0038619, filed in the Korean Intellectual Property Office on Mar. 26, 2025, the entire contents of which application is incorporated herein by reference.

### BACKGROUND

### 1. Field

The present disclosure relates to a method for forming a thin film and a method for manufacturing a device thereof, and more particularly, to a method for forming a chalcogenide-based thin film using an atomic layer deposition process and a method for manufacturing a non-volatile memory device thereof.

### 2. Description of the Related Art

A chalcogenide is a compound consisting of at least one hexavalent (chalcogen) element and one or more electropositive elements. All hexavalent elements are chalcogenic, but oxides that contain no other hexavalent elements besides oxygen are not usually referred to as chalcogenides. Chalcogenides may be characterized by a rapid phase change between crystalline and amorphous states upon application of heat, which may be used to implement non-volatile memory devices with critical switching characteristics.

Chalcogenide-based thin films for non-volatile memory devices are primarily formed by the atomic layer deposition (ALD) process. Due to its self-limited growth nature, the ALD process enables the formation of functional thin films with atomic-scale features conformally on substrates with complex surface structures.

In forming data storage materials applied to non-volatile memory with critical switching characteristics by the ALD process, the precursor material and deposition temperature (process temperature) may have a significant impact on the quality and performance of the data storage materials. Generally, GeTe2 or Ge2Sb2Te(7) (i.e., GST227) materials may be formed by utilizing Ge precursors with a +4 oxidation state of Ge, i.e., Ge(IV) precursors. However, these materials do not have good phase transition properties and suffer from Te precipitation during the phase transition behavior.

On the other hand, because increasing the deposition temperature in the ALD process causes the thin film to be poorly coalesced and fall off, the deposition temperature may be determined in a low temperature range of approximately 70 to 100° C. However, the thin films deposited in this temperature range generally have low density and strength, resulting in poor quality of the thin films and, accordingly, poor phase transition characteristics, which might not be suitable for the realization of memory devices having actual critical switching characteristics. Therefore, there is a need for a method for forming thin films that may be deposited in a high-temperature process in a temperature range above 100° C.

### SUMMARY

According to an embodiment of the present disclosure, a method of forming chalcogenide-based thin film using an atomic layer deposition (ALD) process includes: a first step of supplying, into a reaction chamber equipped with a substrate, a first source gas including a Ge precursor having a +2 oxidation state of Ge; a second step of supplying a first purge gas into the reaction chamber; a third step of supplying into the reaction chamber a second source gas including a Se precursor and a first co-reactant gas to promote a reaction between the Ge precursor and the Se precursor; a fourth step of supplying a second purge gas into the reaction chamber; a fifth step of supplying a third source gas including an In precursor into the reaction chamber; a sixth step of supplying a third purge gas into the reaction chamber; a seventh step of supplying a second co-reactant gas into the reaction chamber to promote a reaction of the third source gas including the In precursor and the second source gas; and an eighth step of supplying a fourth purge gas into the reaction chamber, wherein a supercycle is repeated, the supercycle comprising repeating the first step through the fourth step 7 to 13 times and performing the fifth step through the eighth step once thereafter.

In an embodiment, the supercycle may be repeated 5 to 15 times.

In an embodiment, the Ge precursor may include Ge(II)-guanidinate, and the Ge precursor may include Ge(II)-amido guanidinate.

In an embodiment, the second source gas and the first co-reactant gas may be supplied simultaneously in the reaction chamber.

The third source gas and the second co-reactant gas and the second source gas may be supplied simultaneously in the reaction chamber.

At least one of the first co-reactant gas and the second co-reactant gas may include NH₃.

In an embodiment, in the Se precursor, Se may have an oxidation state of −2, and the Se precursor may include ((CH₃)₃Si)₂Se).

In an embodiment, the deposition temperature during the first through fourth steps for forming a Ge—Se-based material is in the range of 150 to 280° C.

In an embodiment, the In precursor may include Triethyleindium (TEI).

In an embodiment, the deposition temperature is in the range of 150 to 280° C. during the fifth through eighth steps for forming a Ge—Se—In-based material.

In an embodiment, the chalcogenide-based thin film may repeatedly include a Ge—Se material layer and a Ge—Se—In material layer.

In an embodiment, the method of forming a chalcogenide-based thin film using an atomic layer deposition (ALD) process may further include the step of annealing the chalcogenide-based thin film.

In an embodiment, the first step through the fourth step for forming the Ge—Se-based material may be repeated m times, wherein m is an integer greater than or equal to 1, and the fifth step through the eighth step for forming the Ge—Se—In-based material may be repeated n times, wherein n is an integer greater than or equal to 1, and m>n.

### BRIEF DESCRIPTION OF THE DRAWINGS

FIG. 1 is a flowchart illustrating a method of forming a chalcogenide-based thin film by an atomic layer deposition (ALD) process according to an embodiment of the present disclosure.

FIG. 2 illustrates a flowchart of a method for the formation of a chalcogenide-based thin film by an atomic layer deposition (ALD) process according to an embodiment of the present disclosure.

FIG. 3A illustrates an ALD sequence applicable to a conventional method of forming a chalcogenide-based thin film by an atomic layer deposition process, and FIGS. 3B and 3C illustrate an ALD sequence applicable to a method of forming a chalcogenide-based thin film by an atomic layer deposition (ALD) process according to an embodiment of the present disclosure.

FIG. 4 is an example chemical structure formula illustrating a germanium (Ge) precursor that may be applied to a method for the formation of chalcogenide-based thin films by an atomic layer deposition (ALD) process according to an embodiment of the present disclosure.

FIG. 5 is an example chemical structure formula illustrating a selenium (Se) precursor that may be applied to a method for the formation of chalcogenide-based thin films by an atomic layer deposition (ALD) process according to an embodiment of the present disclosure.

FIG. 6 is an example chemical structure formula illustrating an indium (In) precursor that may be applied to a method for the formation of chalcogenide-based thin films by an atomic layer deposition (ALD) process according to an embodiment of the present disclosure.

FIGS. 7A, 7B, and 7C illustrate a method of forming a chalcogenide-based thin film by an atomic layer deposition (ALD) process according to embodiments of the present disclosure.

FIG. 8 illustrates a vertical non-volatile memory device with a vertical stacking structure material according to an embodiment of the present disclosure.

FIGS. 9A and 9B are drawings showing TEM images of a chalcogenide-based thin film deposited on a hole-formed substrate having an aspect ratio of about 32:1, according to an embodiment of the present disclosure.

FIG. 10 is an AES analysis graph showing the concentration of atoms including a chalcogenide-based thin film according to an embodiment of the present disclosure.

FIG. 11 is an XRR analysis graph showing the density of a chalcogenide-based thin film according to an embodiment of the present disclosure.

FIG. 12 is a graph of the results of an XPS analysis of the formation of a Ge—Se material layer in accordance with an embodiment of the present disclosure, for a comparative example deposited by a conventional ALD method and for an embodiment deposited by the DFM method of the present disclosure, in which the constituent materials may be identified.

FIG. 13A illustrates a cross-sectional view of a non-volatile memory device with a Ge—Se material layer according to an embodiment of the present disclosure, and FIGS. 13B and 13C illustrate characteristics of the non-volatile memory device.

FIGS. 14A and 14B show XPS analysis results and SEM analysis results indicating the components of the Ge—Se—In layer according to an embodiment of the present disclosure.

### DETAILED DESCRIPTION

Hereinafter, example embodiments of the present disclosure are described in detail with reference to the accompanying drawings.

The example embodiments described below are provided to further illustrate the disclosure to those having ordinary skill in the art, and the scope of the disclosure is not intended to be limited by the following embodiments, which may be modified in various other ways.

The terms used in this specification are intended to describe example embodiments and are not intended to limit the disclosure. Terms used herein in the singular form may include the plural form, unless the context clearly indicates otherwise. Furthermore, as used herein, the term “connected” is intended to mean not only that certain elements are directly connected, but also that they are indirectly connected by the interposition of other elements between them.

In addition, when the present disclosure refers to a member being located “on” another member, this includes not only when a member is abutting another member, but also when there is another member between the two members. As used herein, the term “and/or” includes any one of the enumerated items and any combination of one or more of them. In addition, the terms “about,” “substantially,” and the like as used in the disclosure are intended to mean at or near the range of numbers or degrees, taking into account inherent manufacturing and material tolerances, and to prevent infringers from taking unfair advantage of the disclosure where precise or absolute numbers are stated, which are provided for the purpose of illustration.

Some embodiments of the present disclosure are directed to a thin film formation method using an atomic layer deposition process capable of forming chalcogenide-based thin films with desirable properties. Additional embodiments are directed to a method for forming thin films using an atomic layer deposition process in which the deposition is carried out in a high temperature range, and chalcogenide-based thin films having desired film quality, phase change properties, critical switching properties, and durability may be formed. Further embodiments provide a method of forming a material layer having a critical switching characteristic and a method of manufacturing a non-volatile memory device by applying the above thin film forming method.

Example embodiments of the present disclosure are described in detail with reference to the accompanying drawings. The sizes or thicknesses of the areas or parts shown in the accompanying drawings may be somewhat exaggerated for clarity and ease of description. Throughout the detailed description, like reference numerals designate like components.

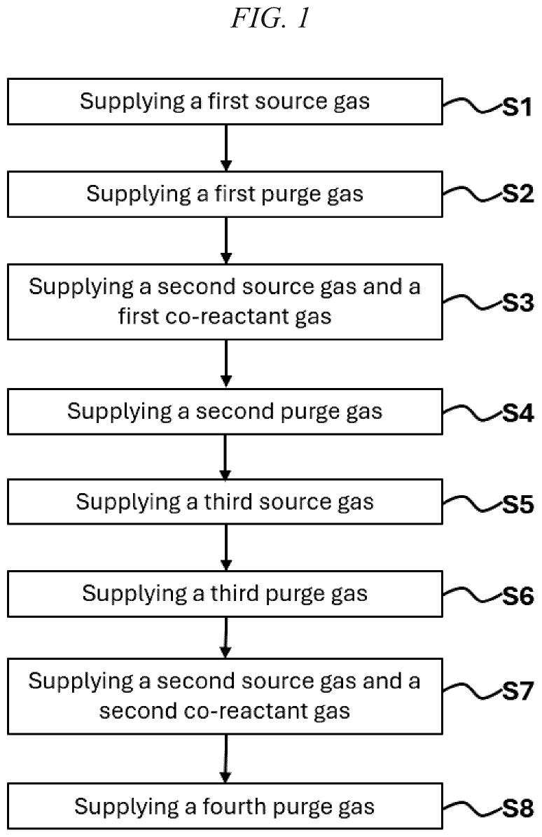

FIG. 1 is a flowchart illustrating a method of forming a chalcogenide-based thin film by an atomic layer deposition (ALD) process according to an embodiment of the present disclosure.

Referring to FIG. 1, a method of forming a chalcogenide-based thin film using an atomic layer deposition (ALD) process according to an embodiment may include forming a Ge—Se-based material. Forming the Ge—Se-based material may include: a first step S1 of supplying a first source gas including a Ge precursor having an oxidation state of Ge of +2, in a reaction chamber (not shown) having a substrate (deposition substrate) (not shown); a second step S2 of supplying a first purge gas in the reaction chamber; a third step S3 of supplying a second source gas including a Se precursor and a first co-reactant gas promoting a reaction between the Ge precursor and the Se precursor within the reaction chamber; and a fourth step S4 of supplying a second purge gas within the reaction chamber.

By using a Ge precursor in which the oxidation state of Ge is +2, i.e., a Ge(II) precursor, it is possible to form GeSe in which Ge and Se form a compound in a substantially 1:1 ratio (i.e., stoichiometric), which may exhibit better phase transition properties than a Ge—Se-based material formed using a Ge(IV) precursor, and might not cause problems such as precipitation of Se during the phase transition operation. Therefore, it may be advantageous to form a chalcogenide-based thin film having desirable properties and characteristics (e.g., a phase change material layer having desirable critical switching properties).

The Ge precursor having a +2 oxidation state of Ge may include, for example, Ge(II)-guanidinate. As a specific example, the Ge precursor may be Ge(II)-amido guanidinate. Ge(II)-amido guanidinate may be represented as Ge(guan)NMe₂, wherein guan may be (ⁱPrN)₂CNMe₂ and Me may represent CH₃. In other words, Ge(II)-amido guanidinate may be represented as Ge^{(II)}N(CH₃)₂[(NiPr)₂CN(CH₃)₂]. Ge(II)-amido guanidinate may be a suitable precursor for relatively higher temperature deposition processes than conventional Ge(IV) precursors.

In this regard, the use of a Ge(II) precursor, such as Ge(II)-amido guanidinate, may be advantageous for increasing the deposition temperature above 100° C. during the ALD process and improving the density, strength, and film quality of the chalcogenide thin film formed. Herein, Ge(II)-guanidinate is exemplified as a specific material of the Ge precursor, i.e., the Ge(II) precursor, but the Ge(II) precursor that may be used in the embodiments is not limited to Ge(II)-guanidinate and may vary.

In the Se precursor, the Se may have an oxidation state of −2. For example, the Se precursor may include C₆H₁₈SeSi₂, which may be Bis(Trimethylsilyl) Selenide(BTMS-Se). However, the specific substance of the Se precursor is only an example and may be varied. The second oxygen gas including the Se precursor may also be referred to as the “reaction gas.”

The first co-reactant gas may play a role in promoting the reaction between the Ge precursor and the Se precursor, for example, as a catalyst, i.e., the first co-reactant gas may be a kind of catalyst. Because the Ge precursor, i.e., the Ge(II) precursor, is more stable than the Ge(IV) precursor, the ALD reaction with the Se precursor might not occur well if the first co-reactant gas is not used.

In this embodiment, the formation of chalcogenide thin films may be facilitated by using a Ge(II) precursor while using a first co-reactant gas capable of promoting the ALD reaction. In an embodiment, the first co-reactant gas may be, for example, NH₃, or a gas including NH₃. The first co-reactant gas may be configured to react with the Se precursor to generate, for example, SeH₂, and the ALD reaction (film formation reaction) may be facilitated by the SeH₂.

The second source gas including the Se precursor and the first co-reactant gas may be supplied simultaneously in the reaction chamber. By simultaneously feeding the second source gas and the first co-reactant gas into the reaction chamber, SeH₂ as described above may be generated in-situ. If the first co-reactant gas is not used, thin film growth might not be achieved due to low reactivity between the Ge precursor and the Se precursor. Also, if the first co-reactant gas is not injected simultaneously with the second source gas but is injected separately into the reaction chamber after the supply of the second source gas and the supply of the second purge gas, the desired thin film growth might not be achieved.

In addition, if the first co-reactant gas is injected separately from the first source gas and the first purge gas, followed by the second source gas and the second purge gas, a Ge-rich film (~60% Ge) may be formed. In addition, if the first co-reactant gas is injected along with (simultaneously with) the supply of the first source gas, followed by the first purge gas, the second source gas, and the second purge gas, a Ge-rich film with a higher Ge content (80% Ge) may be formed.

In addition, if the first co-reactant gas is injected simultaneously with the first source gas and no second source gas is injected, a Ge film may be formed. As in the present embodiment, if the first co-reactant gas is injected simultaneously with the second source gas (i.e., coinjecting), a stoichiometric GeSe film may be readily and well formed.

The first purge gas and the second purge gas may be inert gases such as Ar or N₂. Herein, N₂ gas is illustrated as the first and second purge gas, but the type of purge gas may vary.

On the other hand, the substrate (i.e., the deposition substrate) (not shown) on which the chalcogenide thin film is deposited may be selected from a variety of substrates. For example, the substrate may be composed of Si. In addition, the surface portion of the substrate may be provided with an insulating material layer, may be provided with a conductive material layer (metallic material layer), or may be provided with a mixture of an insulating material layer and a conductive material layer. The insulating material layer may include, for example, SiO₂ and Si₃N₄, and the conductive material layer may include, for example, a metal compound or metal such as TiN. The type/material/composition of the substrate may be varied.

In forming the Ge—Se-based material according to the embodiment described with reference to FIG. 1, the “deposition temperature” may be determined in a range of about 150 to 280° C. Here, the deposition temperature may correspond to the temperature of the substrate at the time of thin film formation, i.e., the ALD thin film deposition process may be performed while the substrate provided in the reaction chamber is heated to the above-mentioned temperature range. The deposition temperature of the ALD process according to the present embodiment may be about 150 to 280° C., in some instances, about 180 to 280° C. The deposition temperature of such a base material may be higher than the deposition temperature in a conventional ALD process (about 70 to 100° C.). In this regard, the thin film formed by the ALD process according to the embodiments may have desirable properties in terms of density, strength, film quality, physical properties, and the like. In addition, the thin film formed by the ALD process according to the embodiments may have desirable phase transition properties, desirable durability, and the like.

After forming a Ge—Se-based material, as described above, forming a Ge—Se—In-based material according to an embodiment of the present disclosure may include forming a Ge—Se—In-based material. Forming the Ge—Se—In material may include forming a Ge—Se-based material and forming a Se—In-based material.

The Ge—Se-based material may be formed by performing the steps S1 to S4 described above 8 to 12 times. In some instances, the Ge—Se-based material may be formed by performing the above steps S1 to S4 10 times. After performing the steps 10 times, the process may include a fifth step S5 of supplying a third source gas including an In precursor into the reaction chamber, a sixth step S6 of supplying a third purge gas into the reaction chamber, a seventh step S7 of supplying a second co-reactant gas into the reaction chamber to promote the reaction of the second source gas and the third source gas including the In precursor, and an eighth step S8 of supplying a fourth purge gas into the reaction chamber.

When the fifth step S5 to the eighth step S8 are performed, there may be residual in the reaction chamber a second oxygen gas including a Se precursor for performing the first step S1 to the fourth step S4. In an embodiment, if there is insufficient second oxygen gas including a Se precursor to chemically react with the third oxygen gas including an In precursor, the second oxygen gas may be further supplied in the reaction chamber when the fifth step S5 is performed.

The In precursor having a +3 oxidation state included in the third source gas may include, for example, triethylindium (TEI). The triethylindium may be a precursor suitable for deposition processes at relatively higher temperatures than conventional In precursors. While triethyleindium is exemplified herein as a specific In precursor, other In precursors may be used in embodiments without limitation.

The second co-reactant gas may play a role in promoting the reaction between the In precursor and the Se precursor, for example, as a catalyst, i.e., the second co-reactant gas may be a kind of catalyst. In the present embodiment, by using the second co-reactant gas that may promote the ALD reaction while using an In precursor, a chalcogenide-based thin film may be formed. The second co-reactant gas may be, for example, NH₃ or a gas including NH₃. The second co-reactant gas may facilitate the ALD reaction (film formation reaction) in which the In precursor and the Se precursor react with each other to form a Ge—Se—In layer.

In an embodiment, the third source gas including the In precursor, the second source gas, and the second co-reactant gas may be supplied simultaneously in the reaction chamber. If the second co-reactant gas is not supplied, thin film growth might not be achieved due to low reactivity between the In precursor and the Se precursor. In addition, if the second source gas and the second co-reactant gas are not supplied simultaneously with the third source gas, and if the first co-reactant gas is supplied separately into the reaction chamber after the supply of the third source gas and the third purge gas, the desired thin film growth might not be achieved properly.

In addition, if the second source gas and the second co-reactant gas are supplied separately after the supply of the second source gas and the second purge gas, and if the third source gas and the fourth purge gas are supplied, a Ge-rich film (~60% Ge) may be formed. In addition, if the first co-reactant gas is supplied along with (simultaneously with) the supply of the second source gas, followed by the second purge gas, the third source gas, and the fourth purge gas, a Ge-rich film with a higher Ge content (~80% Ge) may be formed.

The third and fourth purge gases may be inert gases such as Ar or N₂. In this example, N₂ gas is used as the third and fourth purge gas, but the type of purge gas may vary.

In an embodiment, a chalcogenide-based thin film may be formed using an atomic layer deposition (ALD) process in which the steps S1 through S4 are repeated 90 to 110 times, followed by performing 8 to 12 times supercycles in which the steps S1 through S4 are performed 8 to 12 times and the steps S3 through S8 are performed 1 to 3 times.

Conventionally, it was not possible to form multi-component thin films including dopants such as In in high temperature ranges. However, according to an embodiment of the present disclosure, a method of forming a chalcogenide-based thin film including a Ge—Se material layer including a Ge—Se-based material and a Ge—Se—In material layer including a Ge—Se—In material layer utilizes a Ge—Se material layer that is a binary thin film as a buffer layer. In this case, a Ge—Se—In multi-component material layer including a dopant such as In may be formed on the Ge—Se material layer. Thus, it is possible to form chalcogenide-based thin films using the atomic layer deposition (ALD) process in the high temperature range of 150 to 280° C.

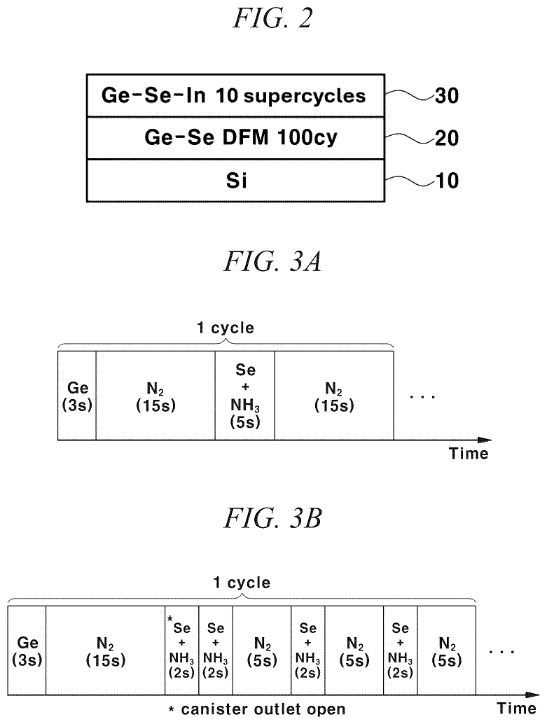

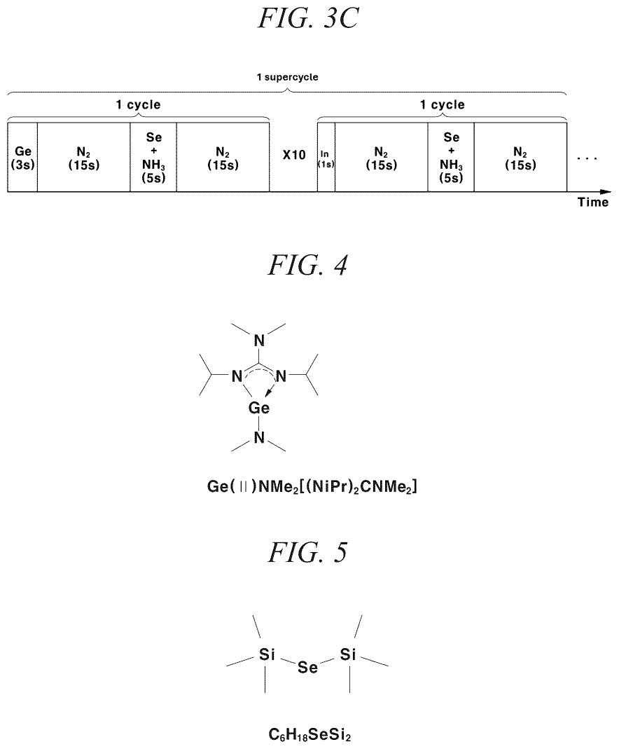

FIG. 2 illustrates a sequence of a method for forming a chalcogenide-based thin film by an atomic layer deposition (ALD) process according to an embodiment of the present disclosure, FIG. 3A illustrates an ALD sequence applicable to a method for forming a chalcogenide-based thin film by a conventional atomic layer deposition process, and FIGS. 3B and 3C illustrate ALD sequences that may be applied to a method for forming a chalcogenide-based thin film by an ALD process according to an embodiment of the present disclosure.

Referring to FIGS. 2 and 3B, the Ge—Se material layer 20 on the silicon substrate 10 may be deposited with a high density and low impurity concentration at a high temperature above 180° C. using a discrete feeding method (DFM) process. The Ge—Se material layer 20 may be formed by repeating the first step S1 to the fourth step S4 80 to 120 times. While the conventional ALD sequence, as shown in FIG. 3A, generated the Ge—Se material layer by a GeSe binary ALD process in a temperature range of 180° C. or lower, the ALD sequence according to an embodiment of the present disclosure, as shown in FIG. 3B, may be performed using a DFM process in a high temperature range of 180° C. or higher.

In some instances, the Ge—Se material layer 20 was deposited in an ALD reactor with a head and substrate heater suitable for the 8-inch wafer scale. The Ge precursor and Se precursor were heated to 65° C. and 35° C. temperatures, respectively, and a gas phase pressure of 0.079 torr and 1 torr was formed. The films were grown on Si/SiO₂ or Si/TiN substrates (where SiO₂ and TiN are the top surface), and the deposition temperature range was approximately 150 to 280° C. The precursors were supplied to the ALD chamber by N₂ carrier gas at a flow rate of 50 sccm, and for the purge process, N₂ gas was injected at 150 sccm. During the deposition, the working pressure in the process chamber (i.e., ALD chamber) was maintained in the range of 4.5 to 5.5 torr. The precursor injection pulse time and purge pulse time were varied.

Referring again to FIG. 3B, the injection/purge time of the Ge precursor may be on the order of, for example, 3 seconds, followed by an injection/purge time of N₂ gas may be on the order of 15 seconds, and the injection/purge time of the Se precursor and NH₃ may be on the order of 2 seconds. Subsequently, the injection/purge time of the N₂ gas may be on the order of 5 seconds, and the injection/purge time of the Se precursor and NH₃ may be on the order of 2 seconds. The injection of the N₂ and Se precursor and NH₃ was performed by the DFM method with the above times repeated. However, these precursor injection/purge times are only examples and may be varied. In addition, the various conditions of the experimental examples described above are only examples and are not intended to be limiting and may be varied. The Ge—Se material layer 20 may be formed by repeating the above DFM method 80 to 120 times.

Referring to FIG. 3C, a Ge—Se—In material layer 30 may be formed on the Ge—Se material layer 20. The Ge—Se—In material layer 30 may be formed by performing the above steps S1 to S4 10 times and then repeating the supercycle of performing the above step S3 to the above step S8 once 10 times. In this case, the first step S1 or the fourth step S4 might not be a DFM method. The ALD sequence according to an embodiment of the present disclosure shown in FIG. 3C may be performed in a high temperature range above 180° C.

In some instances, the Ge precursor for forming the Ge—Se—In material layer 30, the Se precursor, was utilized for deposition under the conditions utilized for the Ge—Se material layer 20. The injection/purge time of the Ge precursor may be, for example, on the order of 3 seconds, followed by the injection/purge time of N₂ gas may be on the order of 15 seconds, and the injection/purge time of the Se precursor and NH₃ may be on the order of 5 seconds. Subsequently, the injection/purge time of the N₂ gas may be on the order of 15 seconds. This cycle may be repeated 10 times. Then, the supply time of the In precursor may be 1 second, followed by a 15 second injection of N₂ gas, and the injection/purge time of the Se precursor and NH₃ may be on the order of 5 seconds, followed by a 15 second injection of N₂ gas. The above deposition process is one supercycle, and the Ge—Se—In material layer 30 may be formed by repeating the above supercycle 10 times.

FIG. 4 is an example chemical structure formula illustrating a Ge precursor that may be applied to a method for the formation of chalcogenide-based thin films by an atomic layer deposition (ALD) process according to an embodiment of the present disclosure.

Referring to FIG. 4, the Ge precursor may be a precursor in which the oxidation state of Ge is +2, such as Ge(II)-amido guanidinate. Ge(II)-amido guanidinate may be represented as Ge(guan)NMe₂, wherein guan may be (ⁱPrN)₂CNMe₂ and Me may represent CH₃. Ge(II)-amido guanidinate may include two anionic ligands, namely, dimethylamino (NMe₂) and bidentate guanidinate [guan=(ⁱPrN)₂CNMe₂] ligands. In addition, Ge(II)-amido guanidinate may have three electron resonance structures in which the p electrons are delocalized to the three C—N bonds. Density functional theory (DFT) calculations show that the bond dissociation energy (BDE) between Ge-guan is about 3.82 eV, which is larger than the BDE between Ge—NMe₂ (about 2.77 eV).

FIG. 5 is an example chemical structural formula showing a Se precursor that may be applied to a method of forming chalcogenide-based thin films by an atomic layer deposition (ALD) process according to an embodiment of the present disclosure. Referring to FIG. 5, the Se precursor is a precursor in which the oxidation state of Se is divalent, such as C₆H₁₈SeSi₂, i.e., BTMS-Se. The substance of the Se precursor is not limited to C₆H₁₈SeSi₂ and may be varied.

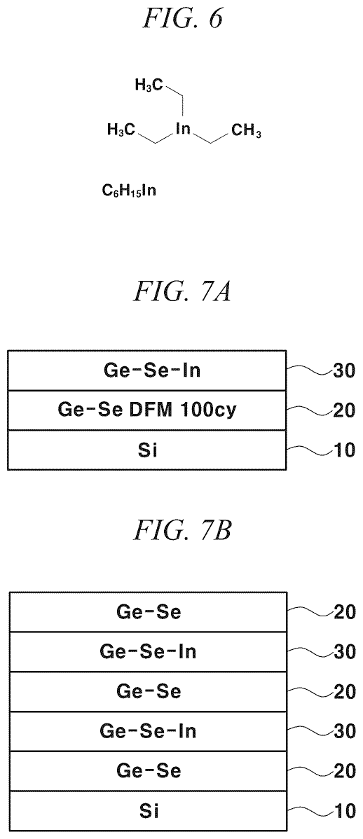

FIG. 6 is an example chemical structural formula showing an In precursor that may be applied to a method of forming chalcogenide-based thin films by an atomic layer deposition (ALD) process according to an embodiment of the present disclosure. Referring to FIG. 6, the In precursor is a precursor in which the oxidation state of In is +3, such as C₆H₁₅In, which may be triethyleindium (TEI). The substance of the In precursor is not limited to TEI and may be varied.

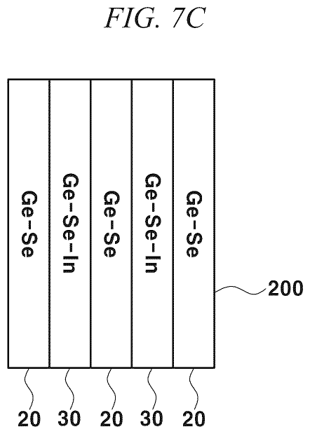

FIGS. 7A to 7C illustrate a method of forming a chalcogenide-based thin film by an atomic layer deposition (ALD) process according to an embodiment of the present disclosure.

Referring to FIG. 7A, as previously shown in FIG. 2, the substrate 10, the Ge—Se material layer 20, and the Ge—Se—In material layer 30 may be formed by the thin film forming method disclosed with reference to FIG. 3. Then, as shown in FIG. 7B, the Ge—Se material layer 20 and the Ge—Se—In material layer 30 may be formed repeatedly in consideration of the characteristics, size, etc. of the device to be applied. The stacking structure material 200 on which the Ge—Se material layer 20 and the Ge—Se—In material layer 30 formed in this way are repeatedly stacked may be vertically arranged as shown in FIG. 7C.

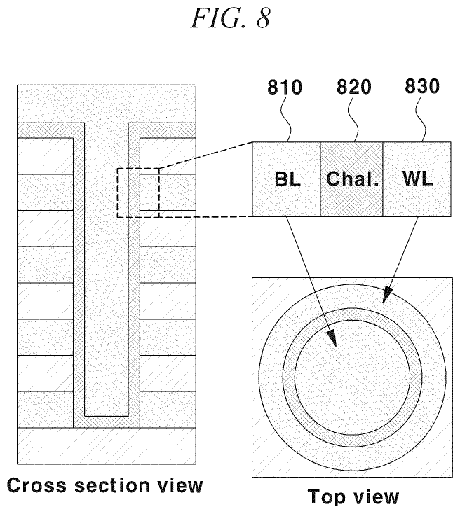

FIG. 8 illustrates a vertical non-volatile memory device with a vertical stacking structural material 200, according to an embodiment of the present disclosure. Referring to FIG. 8, the vertical stacking structural material 200 formed as shown in FIGS. 7A to 7C may be utilized as a functional material layer (e.g., channel layer) of a vertical non-volatile memory device. For example, the vertical non-volatile memory device may be a selector-only memory (SOM) device utilizing the phenomenon of changing a threshold switching voltage, but it is not limited to a SOM device as long as it is a device utilizing the phenomenon of changing a threshold switching voltage.

Referring to the cross-section view and top view of a vertical non-volatile memory device shown at left and right, respectively, in FIG. 8, a bit line 810, BL, may be disposed through the center of the device, and a word line 830, WL, may be disposed parallel to the bit line 810, BL, transversely. In addition, a channel layer 820 may be disposed along the bit line 810 between the bit line 810 and the word line 830. The stacking structure according to an embodiment of the present disclosure is not limited to the structure of the vertical non-volatile memory device shown in FIG. 8, and it may be applied to memory devices having various shapes, as well as to various memory devices that would benefit from improved threshold switching characteristics.

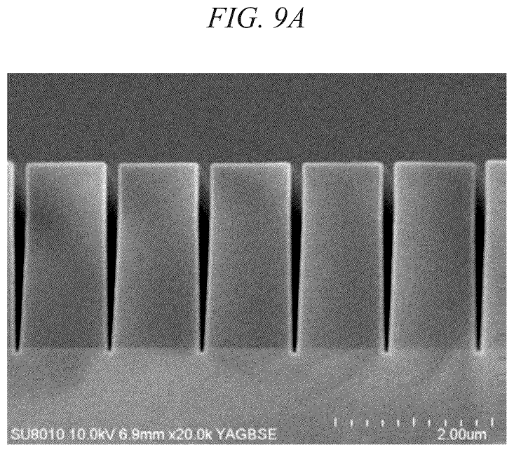

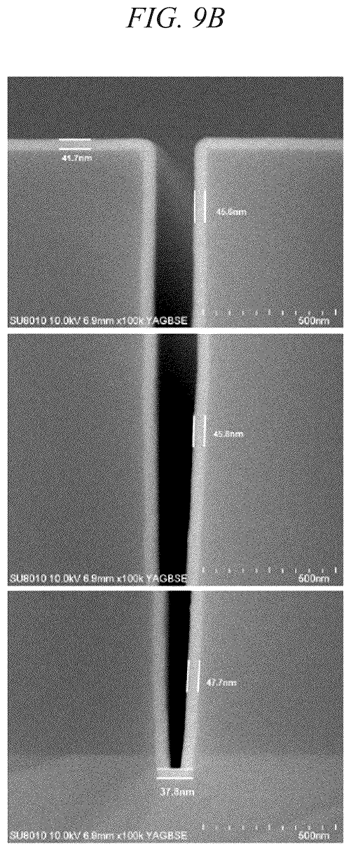

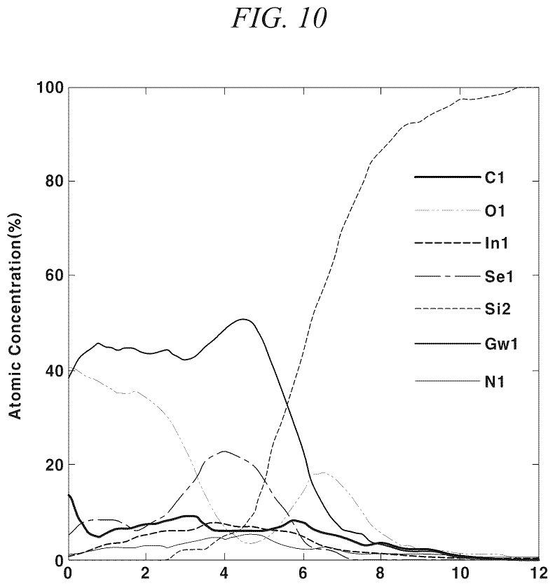

FIGS. 9A and 9B are drawings showing TEM images of a chalcogenide-based thin film deposited on a substrate with holes having an aspect ratio of about 32:1, in accordance with an embodiment of the present disclosure.

Referring to FIG. 9A, it may be seen that the chalcogenide-based thin films are deposited to conformally cover the top surface of the substrate and the interior of the hole with a relatively high aspect ratio. Zooming in and referring to FIG. 9B, the chalcogenide-based thin films according to an embodiment of the present disclosure are deposited with a thickness of 41.7 nm on the top surface of the substrate. It may be seen that the chalcogenide-based thin films are deposited relatively uniformly with thicknesses of 45.6 nm, 45.8 nm, and 47.7 nm on the top region, center region, and bottom region of the sides of the hole, and 37.8 nm on the bottom surface of the hole. That is, 100% of the chalcogenide-based thin films are deposited on the sides of the hole and 90% of the chalcogenide-based thin films are deposited on the bottom surface of the hole.

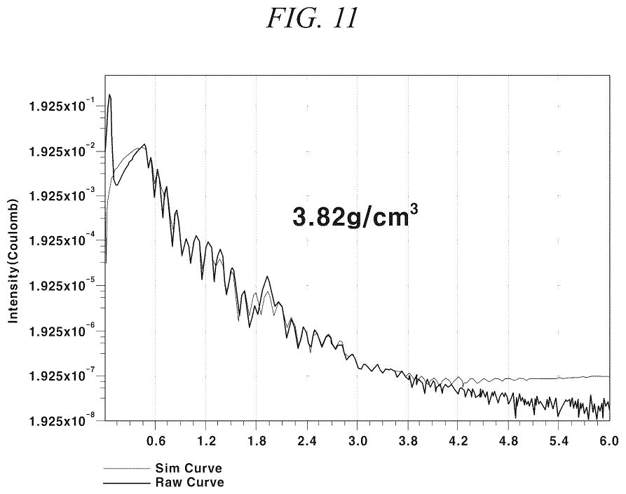

FIG. 10 is a graph showing the results of an AES analysis indicating the concentration of atoms including a chalcogenide-based thin film according to an embodiment of the present disclosure, and FIG. 11 is a graph showing the results of an XRR analysis indicating the density of a chalcogenide-based thin film according to an embodiment of the present disclosure.

Referring to FIGS. 10 and 11, FIG. 10 shows the impurity levels in the chalcogenide thin film. The chalcogenide thin film contained less than 7% impurities of C, O, and N, and also contained 7% In. In addition, the ratio of Ge to Se was 2:1. The atomic percentages of the constituent elements of these chalcogenide thin films are shown in Table 1 below.

TABLE 1

| | C | O | N | Ge | Se | Si | In |
|---|---|---|---|---|---|---|---|
| At % | 6.05 | 6.32 | 3.31 | 48.15 | 24.21 | 4.96 | 7.00 |

Referring to FIG. 11, the density of the chalcogenide-based thin film according to an embodiment of the present disclosure is 3.82 g/cm³. When the theoretical density value is obtained by calculating the molar ratio of Ge—Se thin film to 3.7% In, the value is 5.12 g/cm³. The density of the chalcogenide-based thin film of the present disclosure may be close to the theoretical density, with a density of about 75% of the theoretical density.

Referring again to FIGS. 1 to 3C, thin film formation was performed by selecting BTMS-Se as the Se precursor to form the Ge—Se material layer 20. At this time, experiments were conducted by adjusting the injection time of the Se precursor to increase the content of the Se composition, and the experimental results according to the injection time of the Se precursor are shown in Table 2 below.

TABLE 2

| | | Ge layer | Se layer | |
|---|---|---|---|---|
| Ge07-purge- | Thickness | density | density | |
| BTMS-Se-Purge | (nm) | (μg/cm²) | (μg/cm²) | GeₓSe₁₋ₓ |
| 3 s-15 s-4 s-15 s | 10.13 | 3.445 | 1.187 | 0.74 |
| 3 s-15 s-6 s-15 s | 10.52 | 6.751 | 3.394 | 0.67 |
| 3 s-15 s-8 s-15 s | 12.68 | 7.478 | 3.263 | 0.70 |
| 3 s-15 s-10 s-15 s | 15.19 | 8.275 | 3.072 | 0.73 |

Referring to Table 2, a Ge—Se material layer with the highest percentage of Se was formed when BTMS-Se was supplied for 6 seconds. When BTMS-Se was supplied for a longer time than 6 s, it was also observed that only the composition of Ge increased. This is likely due to the co-injection of BTMS-Se and NH₃, which only increases the composition of Ge.

The results of forming the Ge—Se material layer 20 at various temperatures by applying the Se injection time containing the highest percentage of Se to the Ge—Se material layer 20 identified in Table 2 are shown in Table 3 below.

TABLE 3

| | | Ge layer | Se layer | |
|---|---|---|---|---|
| | Thickness | density | density | |
| Temperature | (nm) | (μg/cm²) | (μg/cm²) | GeₓSe₁₋ₓ |
| 190° C. | 10.32 | 4.83 | 1.02 | 0.83 |
| 220° C. | 10.52 | 6.751 | 3.394 | 0.67 |
| 250° C. | 11.84 | 8.12 | 2.85 | 0.74 |

Referring to Table 3, it may be seen that the density of the Ge layer increases as the temperature of the process increases, while the density of the Se layer is highest at 220° C. Thus, a Ge—Se material layer 20 with the highest Se composition was formed at 220° C.

In addition, in order to improve the deposition of Ge—Se material layer 20, a conventional thin film formation process, a TMA pretreatment process using TMA as a nucleation promoter (Comparative Examples 1 to 3), and a Discrete Feeding Method (DFM) process using short repeated injections of precursors (Embodiment) were applied under 220° C. and 200 cycle conditions, which were identified as optimal conditions in Tables 1 to 3, and the results are shown in Table 4 below.
(Comparison Example 1) Ge07-purge-BTMS-Se OPEN-BTMS-Se(+NH₃)-purge: 3 s-15 s-2 s-4 s-15 s
(Comparison Example 2) Retrying Comparison Example 1
(Comparison Example 3) TMA pulse-{Ge07-purge-BTMS-Se OPEN-BTMS-Se(+NH₃)-purge}: 10 s-{3 s-15 s-2 s-4 s-15 s}
(Example) Ge07-purge-BTMS-Se OPEN-[BTMS-Se(+NH₃)-purge]*3:3 s-15 s-2 s-[2-5]*3

TABLE 4

| | | Ge layer | Se layer | |
|---|---|---|---|---|
| | Thickness | density | density | |
| | (nm) | (μg/cm²) | (μg/cm²) | GeₓSe₁₋ₓ |
| Comparison | 10.52 | 6.751 | 3.394 | 0.67 |
| Example 1 | | | | |
| Comparison | 12.01 | 5.946 | 2.051 | 0.74 |
| Example 2 | | | | |
| Comparison | 12.56 | 4.784 | 1.321 | 0.78 |
| Example 3 | | | | |
| Example | 16.34 | 9.296 | 4.784 | 0.66 |

Referring to Table 4, it may be seen that when the Ge—Se material layer is formed by a conventional thin film formation method such as Comparison Example 1, the reproducibility of the composition is reduced and the density of the overall layer is reduced. In addition, when the TMA pretreatment process is introduced as in Comparison Example 3, the density of the Ge and Se layers is further reduced. On the other hand, when deposited by the DFM method as shown in the Example, a quality Ge—Se material layer 20 with the highest density of Ge and Se layers and a composition of 0.66 may be formed.

Subsequently, the Ge—Se material layer 20 was formed (Experimental Examples 1 to 3) by varying the number of cycles and injection time to determine the conditions of DFM, and the results are shown in Table 5 below, along with a typical thin film formation method (Comparative Example).
(Example 1) DFM 3 cycles, Ge07-purge-BTMS-Se OPEN-[BTMS-Se(+NH₃)-purge]*3: 3 s-15 s-2 s-[2-5]*3
(Example 2) DFM 5 cycles, Ge07-purge-BTMS-Se OPEN-[BTMS-Se(+NH₃)-purge]*5: 3 s-15 s-2 s-[2-5]*5
(Example 3) DFM 5 cycles, Ge07-purge-BTMS-Se OPEN-[BTMS-Se(+NH₃)-purge]*5. 3 s-15 s-2 s-[1-5]*5

TABLE 5

| | | Ge layer | Se layer | |
|---|---|---|---|---|
| | Thickness | density | density | |
| | (nm) | (μg/cm²) | (μg/cm²) | GeₓSe₁₋ₓ |
| Comparison | 12.01 | 5.946 | 2.051 | 0.74 |
| Example | | | | |
| Example 1 | 16.34 | 9.296 | 4.784 | 0.66 |
| Example 2 | 22.91 | 12.596 | 4.430 | 0.74 |
| Example 3 | 11.41 | 5.532 | 2.149 | 0.72 |

Referring to Table 5, it may be seen that when the number of DFM cycle repetitions was increased to 5 cycles, the density of the Ge layer increased while the density of the Se layer was maintained, resulting in a Ge-rich composition, and when the number of DFM cycle repetitions was fixed at 5 cycles and the injection time of the BTMS-Se was reduced to 1 second, the density of the Ge and Se layers was lower and a more Ge-rich composition was formed than at 3 cycle repetitions. Therefore, it may be seen that the Ge—Se material layer 20 has the largest density of the Se layer in the case of Example 1 and may be deposited smoothly.

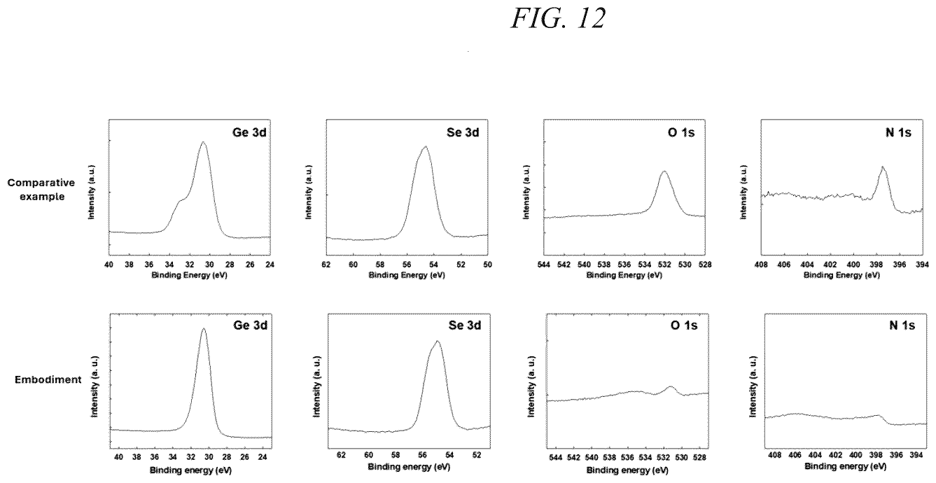

FIG. 12 is a graph of XPS analysis results to determine the constituent materials in the formation of a Ge—Se material layer according to an embodiment of the present disclosure, when deposited by a conventional ALD method (Comparison Example) and when deposited by the DFM method of the present disclosure (Example).

Referring to FIG. 12, it may be seen that the O is and N is peaks are reduced for the embodiment deposited by the DFM method compared to the comparative embodiment deposited by the conventional ALD method. Therefore, the Ge—Se material layer 20 according to an embodiment of the present disclosure may be formed with a reduced content of impurities.

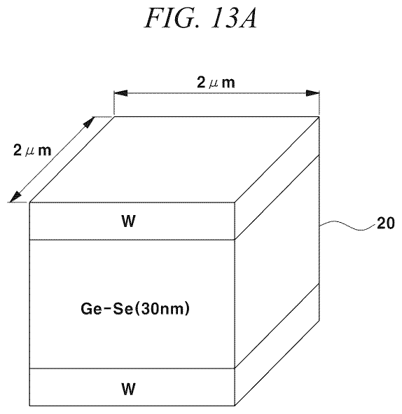

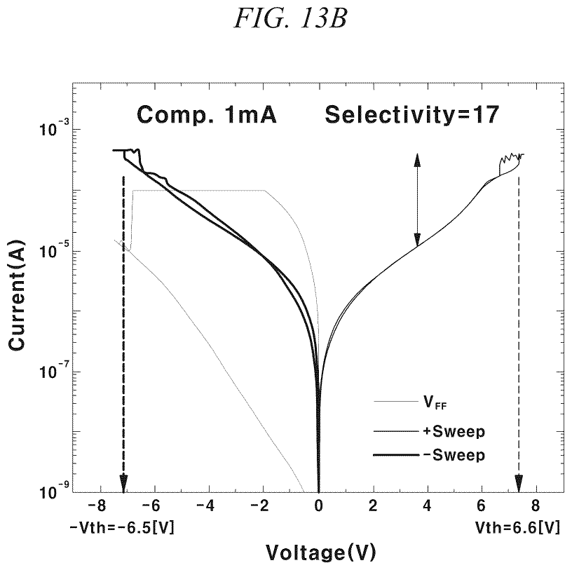

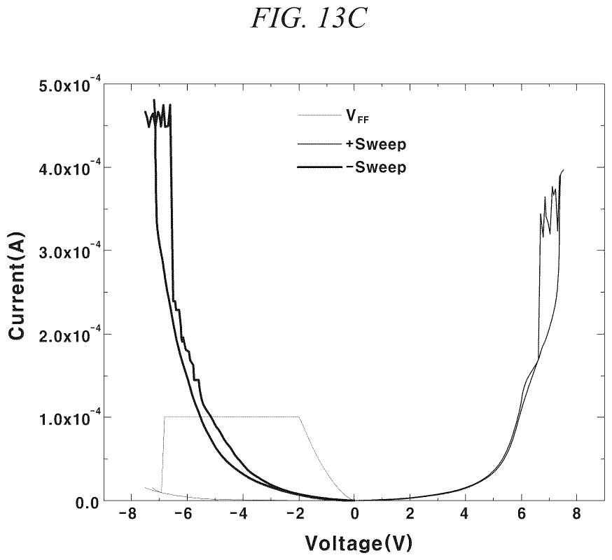

FIG. 13A illustrates a cross-sectional view of a non-volatile memory device with a Ge—Se material layer 20 according to an embodiment of the present disclosure, and FIGS. 13B and 13C illustrate characteristics of the non-volatile memory device.

Referring to FIG. 13A, a non-volatile memory device including a Ge—Se material layer 20 was fabricated by depositing a Ge—Se material layer 20 at 220° C. for 200 cycles using the DFM method described in FIG. 3B, the memory device including tungsten electrodes on the top and bottom of the Ge—Se material layer 20. Referring to FIGS. 13B and 13C, when −6.8 V is applied as a forming voltage to the non-volatile memory device of FIG. 13A, a threshold switching voltage characteristic of +sweep Vₜₕ=6.6[V]/−sweep Vₜₕ=−6.5[V] is shown. In addition, it is confirmed that the threshold switching voltage characteristic is +sweep Vₜₕ=6.6[V]/−sweep Vₜₕ=−6.5[V], and the on/off ratio is about 17, and the characteristics of Vₜₕ and the selectivity ratio are similar in both directions.

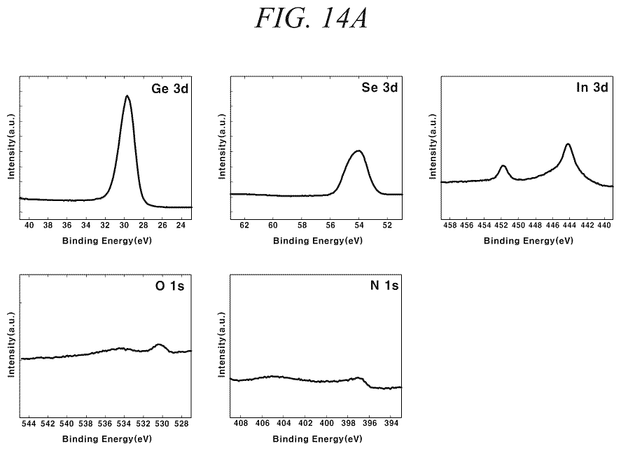

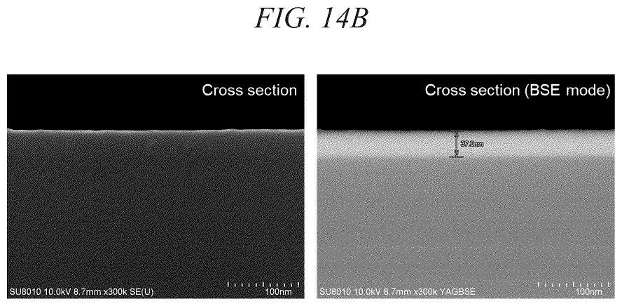

FIGS. 14A and 14B show XPS analysis results and SEM analysis results indicating the components of the Ge—Se—In layer according to an embodiment of the present disclosure.

The DFM process previously applied to form the Ge—Se material layer 20 may also be applied to the deposition process of the Ge—Se—In material layer 30. In this case, the DFM process may be used to form the Ge—Se film first, followed by the deposition of In. Otherwise, the deposition method of the Ge—Se—In material layer 30 may be performed identically to the process described with reference to FIGS. 1 to 3C.

Referring to FIG. 14A, in the Ge—Se—In material layer 30 according to an embodiment of the present disclosure, a peak of In was identified in addition to Ge and Se, and when the atomic percentage was checked, about 3.7% In was identified. Referring to FIG. 14B, it may be seen that the Ge—Se—In material layer 30 of about 37 nm thickness was formed by the formation method of the chalcogenide-based thin film according to an embodiment of the present disclosure.

According to embodiments of the disclosure described above, an atomic layer deposition process may be utilized to form chalcogenide-based thin films having desirable properties. In particular, according to the embodiments, the atomic layer deposition process may be used to facilitate the formation of chalcogenide-based thin films having desirable film quality, desirable phase change properties, desirable threshold switching properties, and desirable durability. By applying thin film formation methods according to these embodiments, non-volatile memory devices with desirable performance may be realized.

This description discloses example embodiments of the present disclosure, and although certain terms are used, they are used in a general sense only to facilitate the description and understanding of the disclosure and are not intended to limit the scope of the disclosure. In addition to the example embodiments disclosed herein, other modifications based on the technical ideas of the present disclosure are possible, as will be apparent to those of ordinary skill in the art to which the present disclosure belongs. One having ordinary knowledge in the art will recognize that the method of forming chalcogenide-based thin films using the atomic layer deposition process described with reference to FIGS. 1 to 13B, and the method of fabricating non-volatile memory devices having desirable threshold switching characteristics using the same, may be subject to various substitutions, changes, and/or modifications without departing from the technical idea of the disclosure. The scope of the disclosure is therefore not to be defined by the described example embodiments, but rather by the technical concepts recited in the patent claims.

1. A method of forming a chalcogenide-based thin film using an atomic layer deposition (ALD) process, the method comprising:
a first step of supplying, into a reaction chamber equipped with a substrate, a first source gas comprising a Ge precursor having a +2 oxidation state of Ge;
a second step of supplying a first purge gas into the reaction chamber;
a third step of supplying into the reaction chamber a second source gas comprising a Se precursor and a first co-reactant gas to promote a reaction between the Ge precursor and the Se precursor;
a fourth step of supplying a second purge gas into the reaction chamber;
a fifth step of supplying a third source gas comprising an In precursor into the reaction chamber;
a sixth step of supplying a third purge gas into the reaction chamber;
a seventh step of supplying a second co-reactant gas into the reaction chamber to promote a reaction of the third source gas comprising the In precursor and the second source gas; and
an eighth step of supplying a fourth purge gas into the reaction chamber,
wherein a supercycle is repeated, the supercycle comprising repeating the first step through the fourth step 7 to 13 times and performing the fifth step through the eighth step once thereafter.

2. The method of claim 1, wherein the supercycle is repeated 5 to 15 times.

3. The method of claim 1, wherein the Ge precursor comprises Ge(II)-guanidinate.

4. The method of claim 3, wherein the Ge precursor comprises Ge(II)-amido guanidinate.

5. The method of claim 1, wherein the second source gas and the first co-reactant gas are simultaneously supplied into the reaction chamber.

6. The method of claim 1, wherein the third source gas, the second co-reactant gas, and the second source gas are simultaneously supplied into the reaction chamber.

7. The method of claim 1, wherein at least one of the first co-reactant gas and the second co-reactant gas comprises NH₃.

8. The method of claim 1, wherein the Se precursor has an oxidation state of −2.

9. The method of claim 1, wherein the Se precursor comprises ((CH₃)₃Si)₂Se).

10. The method of claim 1, wherein the deposition temperature during the first through fourth steps for forming a Ge—Se-based material is in the range of 150 to 280° C.

11. The method of claim 1, wherein the In precursor comprises triethyleindium (TEI).

12. The method of claim 1, wherein the deposition temperature is in the range of 150 to 280° C. during the fifth through eighth steps for forming a Ge—Se—In-based material.

13. The method of claim 1, wherein the chalcogenide-based thin film repeatedly comprises a Ge—Se material layer and a Ge—Se—In material layer.

14. The method of claim 1, further comprising:
annealing the chalcogenide-based thin film.

15. A method of forming a phase change material layer, the method comprising forming a chalcogenide-based thin film using the method of any one of claim 1.

16. A method of manufacturing a non-volatile memory device, the method comprising:
forming a phase change material layer using the method of claim 15; and
forming an electrode structure for applying a voltage to the phase change material layer.
